(19) United States
(12) Patent Application Publication
(10) Pub. No.: US 2025/0318084 A1
(43) Pub. Date: Oct. 9, 2025

(54) A SYSTEM AND METHOD FOR COOLING INDIVIDUAL SERVERS WITHIN A SERVER CABINET

(71) Applicant: Shimon Ryland, Middleburg, VA (US)

(72) Inventor: Shimon Ryland, Middleburg, VA (US)

(21) Appl. No.: 18/863,137

(22) PCT Filed: May 5, 2023
(86) PCT No.: PCT/US2023/021096

§ 371 Date: Nov. 5, 2024

Related U.S. Application Data
(60) Provisional application No. 63/338,952, filed on May 6, 2022.

(51) Int. Cl. H05K 7/20; G06F 1/20

(52) U.S. Cl. CPC H05K 7/20781; G06F 1/20; H05K 7/20263; H05K 7/20272; H05K 7/20772; G06F 2200/201

(57) ABSTRACT

A system for cooling individual servers in a cabinet has a cabinet having at least one shelf. An envelope is disposed on the at least one shelf. A dagger receiving a server therein is disposed in the envelope A first tank contains a fluid is disposed in the cabinet and is in fluid communication with the envelope. A second tank for containing the fluid is disposed in the cabinet and is in fluid communication with the envelope. The envelope is disposed between the first tank and the second tank; the fluid flowing from the first tank through the envelope to the second tank as a function of gravity. A pump transports the fluid from the second tank to the first tank.

### CROSS-REFERENCE TO RELATED APPLICATIONS

This application claims the benefit of U.S. Provisional Application No. 63/338,952 filed on May 6, 2022, the entire disclosure of which is hereby incorporated in its entirety.

### BACKGROUND OF THE INVENTION

The present invention is directed to a structure and method for cooling server components disposed in a cabinet, and more particularly circulating a heat transfer liquid to individual server components disposed in the cabinet using a water cascade flow path.

With the advent of e-commerce, data dependent economies, and even block chain business models, the demand for servers, both dedicated and cloud based has grown exponentially. However, this growth has resulted in a corresponding growth in servers; usually housed together in specially equipped warehouses. While providing efficiencies in access to the Internet and economies of scale, they suffer from the disadvantage that the servers get extremely hot and collectively raise the temperature of the warehouse in which they are located. Additionally, with increased heat the servers become inefficient, if not inoperable.

It is known in the art to cool server rooms with air conditioning and even fans, but this can be costly, requires special equipment and may not sufficiently lower the temperature at the server. In short it is an inefficient method, driving up the demand for electricity. Use of liquid to cool server cabinets is also known, but they suffer from the disadvantage that they cannot sustain fiber connections, thus limiting bandwidth and connectivity.

Accordingly, a structure and methodology for overcoming the shortcomings of the prior art is provided.

### SUMMARY OF THE INVENTION

A system for cooling individual servers in a cabinet has a cabinet having at least one shelf. An envelope is disposed on the at least one shelf. A dagger receiving a server therein is disposed in the envelope A first tank contains a fluid and is disposed in the cabinet and is in fluid communication with the envelope. A second tank for containing the fluid is disposed in the cabinet and is in fluid communication with the envelope. The envelope is disposed between the first tank and the second tank; the fluid flowing from the first tank through the envelope to the second tank as a function of gravity. A pump transports the fluid from the second tank to the first tank.

In accordance with one embodiment of the invention, the pump is a centrifuge pump, the fluid cascading under the force of gravity form the first tank through the envelope and dagger to the second tank. The fluid is preferably a dielectric fluid capable of transferring heat from the dagger and releasing the heat downstream of the envelope.

In accordance with another embodiment of the invention, a heat sink is disposed between the envelope and the second tank for removing heat from the liquid. Furthermore, the system for cooling individual servers defines a closed loop system.

### BRIEF DESCRIPTION OF THE DRAWINGS

The present disclosure will be better understood by reading the written description with reference to the accompanying drawing figures in which like reference numerals denote similar structure and refer to like elements throughout in which:

FIG. 1 a front plan view of a system for cooling a server constructed in accordance with the invention;

FIG. 2 is a rear plan view of a system for cooling a server constructed in accordance with the invention;

FIG. 3 is a left side plan view of a system for cooling a server constructed in accordance with the invention, showing a bank of servers removed the therefrom;

FIG. 4 is a right side plan view of a system for cooling a server constructed in accordance with the invention;

FIG. 5 is a side plan view of a dagger being inserted into an envelope in accordance with the invention; and

FIG. 6 is a rear plan view of a dagger being inserted into an envelope in accordance with the invention.

### DETAILED DESCRIPTION OF THE PREFERRED EMBODIMENTS

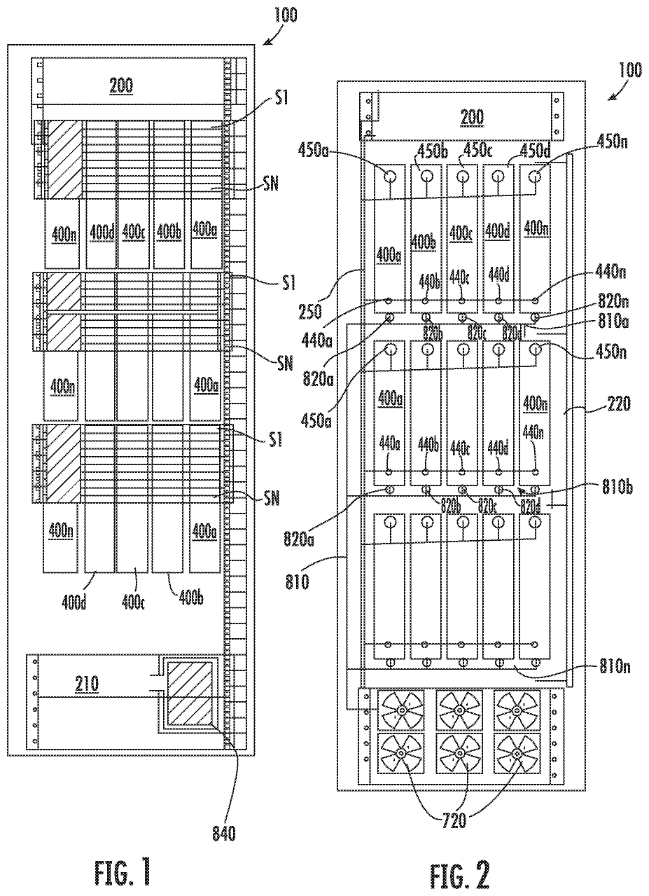

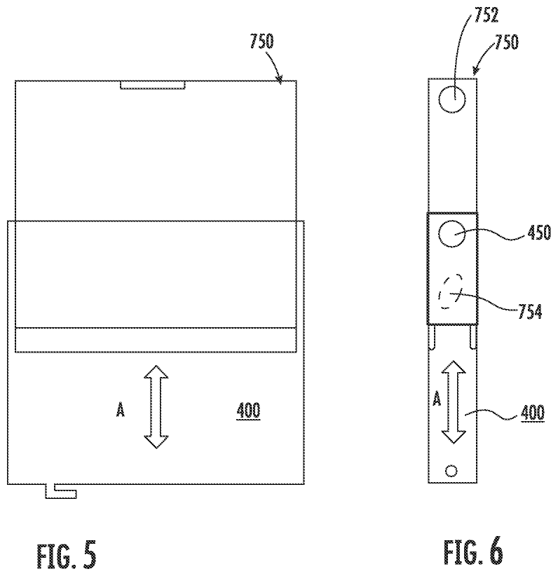

Reference is first made to FIGS. 1, 2 and 3 in which a server cabinet 100, constructed in accordance with the invention is provided. A cabinet 100 includes a plurality of shelves 310a-310n as known in the art. A plurality of envelopes 400a-400n are releasably disposed along each of a respective shelf 310. Each envelope 400 houses a respective dagger 750 (FIGS. 5,6) which in turn holds a respective server board S in the envelope 400.

As can be seen a respective dagger 750 is slidably inserted into, or removed from, a respective envelope 400 by sliding dagger 750 in the respective directions of double headed arrow A into and out of envelope 400. Dagger 750 is in fluid communication with envelope 400 and fills with fluid as envelope 400 fills with fluid as described below. Fluid enters dagger 750, from envelope 400, at a quick connect port 754 and fills dagger 750 until the fluid reaches the level of a quick connect exit port 752, where it then flows to envelope 400.

A first tank 200 is disposed in and supported by cabinet 100. A second tank 210, in fluid communication with tank 200, is disposed in and supported by cabinet 100. In a preferred non limiting embodiment shelves 310a-310n are disposed between tank 200 and tank 210; tank 200 being disposed in the cabinet 100 above tank 210. Furthermore, tank 210 may have a larger volume than tank 200.

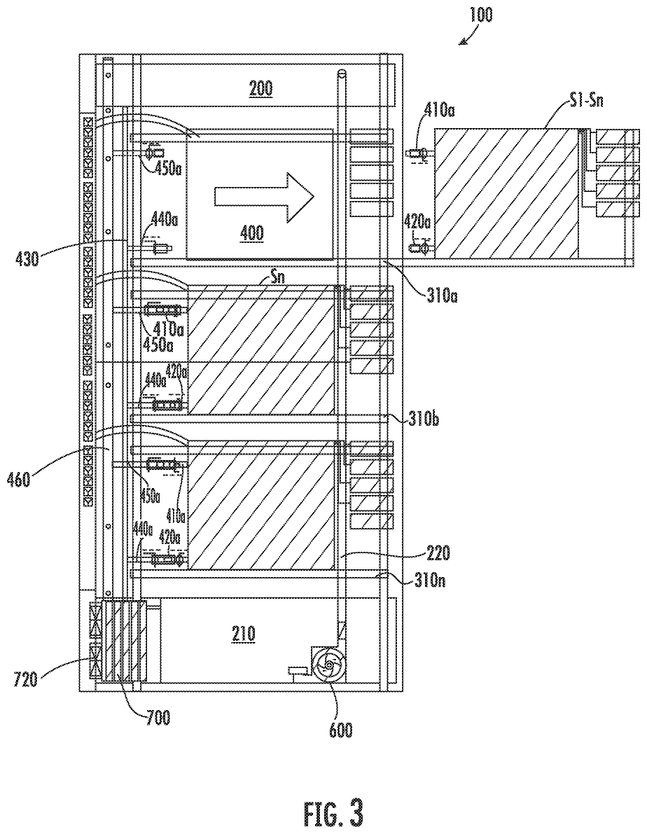

As seen in FIG. 3 tank 210 is in fluid communication with tank 200 along a pipe 220. A pump, preferably a centrifuge 600, in a non-limiting embodiment, transports fluid from tank 210 to tank 200 along pipe 220.

A dagger supply pipe 430 is in fluid communication with tank 200 and tank 210. A dagger drainpipe 460 is in fluid communication with at least tank 210. A first rack quick connect 440a is in fluid communication with dagger supply pipe 430a and is positioned to extend into a shelf 310. A second rack quick connect 450a is in fluid communication with dagger drainpipe 460 and extends into shelf 310 at a position higher than first rack quick connect 440a.

Each envelope 400a-400n disposed on a first shelf 310a, by way of example, includes a respective first fluid quick connect 410a-410n along a respective side wall of envelope 400a-400n and a second quick connect 420a-420n disposed along a side wall of each respective envelope 400a-400n at a position lower than quick connect 410a. Both quick connect 410a and 420a are in fluid communication with an interior of envelope 400a. When an envelope 400a is disposed on a shelf 310a, first fluid quick connect 420a selectively engages first rack quick connect 440a and second quick connect 410a engages rack quick connect 450a.

In this way fluid enters envelope 400a through quick connect 420a. The fluid level rises until it is as high as quick connect 410a which then acts as a self-leveling drain. The fluid flows to dagger 750 as described above, entering quick connect port 754, filling dagger 750 until the liquid reaching quick connect exit port 752 then to envelope 400 and in turn drainpipe 460 and then to tank 210. The fluid, after treatment, as described below, is then pumped by pump 600 through pipe 220 to tank 200 to begin the process again.

A fluid flow path is established from tank 200 through dagger supply pipe 430 to an individual envelope 400 through the connection of quick connects and then to a respective dagger 750. Fluid fills the interior of dagger envelope 300a, and in turn dagger 750, until fluid rises to the level of quick connect 410a. The fluid can be any fluid capable of removing the heat from the envelope 400 as it flows therethrough. In a preferred non limiting embodiment the fluid is brayco micronic 889, sds #454448.

The above description of a single envelope was by way of example only. Each envelope 400a-400n on each shelf 310 is in fluid communication with tank 200 and tank 210 as described above. One or more envelopes 400a-400n daggers 750 (having servers therein and identified as S1-Sn) are disposed on a respective shelf 310. A respective dagger 750 is selectively disposed in a respective envelope 400 which in turn is in fluid communication with dagger supply pipe 430 and drainpipe 460.

In this way, the fluid fills from the bottom of the envelope 400 up providing constant fluid on the heated components to maintain a level temperature. The dagger 750 is fed with cool fluid from the bottom of the envelope 400 and the heated fluid cascades out of the dagger 750 at the top of the envelope 400. The envelope 400 provides the connection points for fluid to flow through the dagger 750. Dagger 750 is the mechanism that holds the server boards S in the envelope. In a preferred non limiting embodiment it has a magnetic lock that releases the board S from the dagger 750 when server S is shutdown or put into service mode.

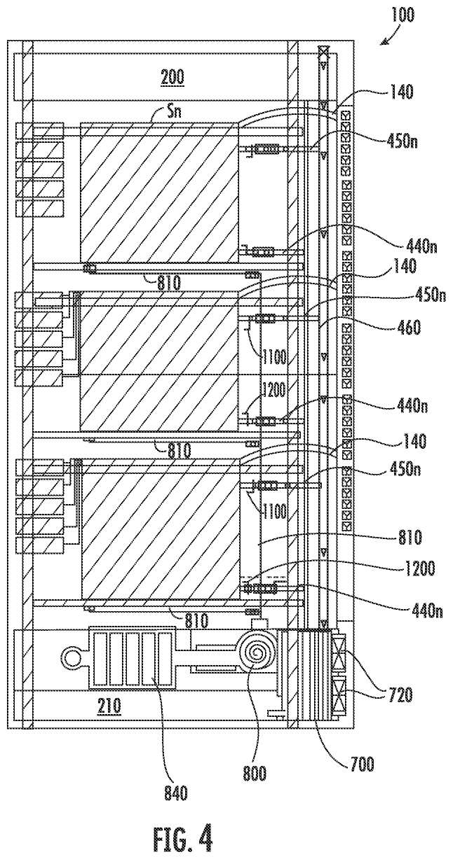

As seen in FIG. 4, each envelope 400a-400b is operatively coupled to a vacuum pump 800 disposed in cabinet 100. A vacuum line 810 branches to operatively couple pump 800 to a series of vacuum lines 810a-810n disposed along a respective shelf 310. A plurality of valves 820a-820n extend from each respective vacuum line 810 along a respective shelf 310 to be in fluid communication with a respective envelope 400a-400n. Pump 800 will engage directly and remove all fluid from the dagger 750 disposed within the envelope 400 upon removal of a server S from the dagger and/or envelope 400. The vacuum line maintains constant vacuum to each envelope 400a-400n because of the vacuum pump 750 at the bottom of the cabinet 100.

As fluid leaves each envelope 400 and/or dagger 750 it has become heated as part of the cooling process for the server S. The heat must be removed from the heated fluid before being returned to tank 200. Therefore, in a preferred non limiting embodiment a heat exchanger 700 is disposed between dagger supply pipe 430 and drainpipe 460 and tank 210 for removing heat from the fluid. In a preferred, non-limiting embodiment fans 720 are provided to cool heat exchanger 700. In one non limiting embodiment, heat exchanger 700 may include chill lines. In a preferred non limiting embodiment, to maximize cabinet space amongst adjacent cabinets, heat exchanger 700 is disposed within cabinet 100.

To control the temperature of each server, heat sensors are disposed inside the dagger envelope 400 reading the fluid temperature at the incoming point (the bottom) and the cascade out (top). All those temperatures are communicated back to a control (either on the cabinet or remote therefrom) that adjust the flow rate to the envelope 400. The flow rate is adjusted by a flow control valve 1100 located at the first fluid quick connect 410 at the top of the feedline and a flow control valve 1200 located along second fluid quick connect 420; a respective manifold for each envelope 400a-400n has a respective flow control valve. The temperature data controls the flow control valves 1100a-1200n associated with each envelope 400. The flow valves 1200a-1200n report to a main control board (not shown) that is monitored electronically and automatically.

The flow rate can be adjusted manually by logging into a remote dashboard communicating with the appropriate valves. In a preferred non-limiting embodiment, the sensors are hardwired to the control board. As can be seen, the temperature is monitored, and flow rate is adjusted by temperature readings.

In a preferred, non-limiting embodiment, a temperature sensor is located in the bottom of tank 210 and a temperature sensor in the top tank 200, each reporting to the head-end which is the control module that controls the system. There will also be a temperature sensor on the collection side of the heat exchanger 700, deposit side and on the external coolant into the heat exchanger 700 and out going from the heat exchanger 700.

Each envelope 400 is designed to house the components of the server that create heat. Each envelope 400, used in combination with a dagger will fit multiple types of CPUs, GPUs, power supplies, hard drives with its adjustable design. As a result, the envelope/dagger solution of the present invention encompasses practicality of deployment, serviceability and optimum functionality using gravity as its main force of supply and collection. As seen from the figures, the envelope 400 houses the dagger that holds the server boards S in the envelope 400 so the fluid can fill from the bottom of the envelope up providing constant fluid on the heated components to maintain a level temperature. The dagger is fed with cool fluid from the bottom of the envelope 400 and the fluid cascades out at the top of the envelope.

As seen in FIG. 3, all the cable management comes in from a bundle of cables, power and/or communication, collectively labeled as cable 140 adjacent the top of the envelope 400. The dagger envelope 400 has adjustable cascade points so that it does not fill above the electrical or fiber or server ribbon connection points.

In a preferred non limiting when the server S is put in service mode or powered down it disengages a magnetic lock that allows the dagger 750 to be pulled from the envelope 400 which breaks the vacuum seal between the envelope 400 and dagger 750 and when the dagger 750 is pulled out the vacuum line 810 is engaged to suck the fluid from the envelope 400 immediately ensuring there is no leakage of fluid. The vacuum pump 800 dumps the fluid into the gravity fed tank 210.

This solution provides a gravity fed delivery system to cool server components. The fluid is pulled from the bottom tank 210. The fluid is moved from the bottom tank up to the top tank 200 via a centrifuge pump 600. Centrifuge pump 600 eliminates typical pump failure, due to high viscosity of the cooled fluid. This design uses an encasing around each server motherboard “dagger envelope”, using fluid displacement process to cascade cooled fluid across server components. Heat sensors will monitor temperature and control fluid application.

In the envelope 400, the dagger 750 is removable for serviceability and new component replacement. When dagger is in service mode “out”, a vacuum line 810 will engage and extract all fluid from the envelope 400. The dagger pushed into the envelope and in “operation” mode will have cooled fluid filling up the envelope and cascading hot fluid out to collection. The hot fluid uses gravity to reach the bottom where it goes through a heat exchanger 700 and the cooled fluid collects in the bottom tank.

As a result of the above construction, this design can be used in many environments. In a data center environment, the solution will significantly reduce the carbon footprint, cost of energy, and eliminate the need for mass chillers for servers. Fluid cascade cooling allows for computer components to be cooled by directing fluid on the heated components in an individualized “dagger envelope” environment, where the cold fluid displaces the heated fluid in a cascade. The fluid is directed to the components based on sensors that gauge temperature and allow fluid to increase as the temperature rises. This invention is a mobile, user-friendly solution as it requires minimum fluid and uses a Centrifuge pump to move the fluid from the base to the top and gravity to deliver the fluid to the envelope where it cascades over the server components. An entire motherboard is disposed in the envelope, but because of the envelope/dagger structure, the connectors to a particular board are above the fluid which allows connection to the fiber. The fluid is collected at the base of the unit where it is cooled and pumped back to the top via the pump. The serviceability design is a unique aspect, not available on the market currently. By creating a separate dry and wet side for the cabinet the hot server components can be allocated to the fluid cooled, wet side while maintaining the dry side for non-heating components which allows for either copper or fiber connections. consumers.

It will thus be seen that the objects set forth above, among those made apparent from the preceding description, are efficiently attained and, since certain changes may be made in carrying out the above method and in the construction set forth without departing from the spirit and scope of the invention, it is intended that all matter contained in the above description and shown in the accompanying drawings shall be interpreted as illustrative and not in a limiting sense.

It is also to be understood that the following claims are intended to cover all of the generic and specific features of the invention herein described, and all statements of the scope of the invention which, as a matter of language, might be said to fall therebetween.

1. A system for cooling individual servers in a cabinet comprises:
a cabinet having at least one shelf;
at least one envelope disposed on the at least one shelf;
a dagger for receiving a server therein disposed in the at least one envelope;
a first tank for containing a fluid is disposed in the cabinet and is in fluid communication with the at least one envelope;
a second tank for containing the fluid is disposed in the cabinet and is in fluid communication with the at least one envelope; the envelope being disposed between the first tank and the second tank; the fluid flowing from the first tank through the envelope to the dagger and from the dagger to the envelope to the second tank as a function of gravity; and
a pump, the pump transporting fluid from the second tank to the first tank.

2. The system of claim 1, further comprising a heat sink disposed between the envelope and the second tank.

3. The system of claim 1, wherein the first tank is disposed above the second tank.

4. The system of claim 1, further comprising a dagger supply pipe in fluid communication with the first tank, second tank and the at least one envelope, the dagger supply pipe conveying the fluid between the first tank and the second tank; and a dagger drain pipe in fluid communication with the at least one envelope and the second tank, the dagger drain pipe being in fluid communication with the at least one envelope at a position along the at least one envelope higher than a position at which the dagger supply pipe is in fluid communication with the at least one envelope.

5. The system of claim 4, further comprising a cable communicating with server, the cable being disposed above the envelope.

6. The system of claim 4, further comprising a first rack quick connect for connecting the dagger drainpipe in fluid communication with the at least one envelope.

7. The system of claim 4, further comprising a second rack quick connect for connecting the dagger supply pipe in fluid communication with the at least one envelope.

8. The system of claim 1, further comprising a server selectively disposed within the dagger.

9. The system of claim 1, further comprising a first quick connect extending from the envelope in fluid communication with an interior of the envelope.

10. The system of claim 9, further comprising a second quick connect extending from the envelope in fluid communication with an interior of the envelope; the first quick disconnect extending at a position along the envelope above a position the second quick disconnect extends from the envelope.

11. The system of claim 4, further comprising a first rack quick connect for connecting the dagger drain pipe in fluid communication with the at least one envelope; a second rack quick connect for connecting the dagger supply pipe in fluid communication with the at least one envelope; a first quick connect extending from the envelope in fluid communication with an interior of the envelope and selectively connecting to the first rack quick connect; a second quick connect extending from the envelope in fluid communication with an interior of the envelope; the first quick disconnect extending at a position along the envelope above a position the second quick disconnect extends from the envelope and selectively engages the second rack quick connect.

12. The system of claim 1, further comprising a cable connect extending into the envelope at a position above a position the second quick disconnect extends from the envelope.

13. The system of claim 1, further comprising a suction line in fluid communication with the envelope and the second tank, the suction line removing the fluid in the envelope upon removal of the server from the envelope.
